(19) United States
(12) Patent Application Publication
(10) Pub. No.: US 2015/0060784 A1
(43) Pub. Date: Mar. 5, 2015

(54) ORGANIC LIGHT EMITTING DISPLAY AND METHOD FOR MANUFACTURING THE SAME

(71) Applicant: SAMSUNG DISPLAY CO., LTD., Yongin-City (KR)

(72) Inventors: Sun Hee Lee, Seoul (KR); Young Gug Seol, Hwaseong-si (KR); Ju Chan Park, Seoul (KR); Jin Woo Lee, Suwon-si (KR); Pil Suk Lee, Seoul (KR); Hui Ying Li, Yongin-si (KR)

(73) Assignee: SAMSUNG DISPLAY CO., LTD., Yongin-City (KR)

(21) Appl. No.: 14/253,726

(22) Filed: Apr. 15, 2014

(30) Foreign Application Priority Data
Sep. 3, 2013 (KR) 10-2013-0105394

(51) Int. Cl. H01L 27/32; H01L 51/56

(52) U.S. Cl. CPC H01L 27/3244; H01L 51/56
USPC 257/40; 438/23

(57) ABSTRACT

A method of manufacturing an organic light emitting display includes: patterning an amorphous silicon layer to form an amorphous silicon layer pattern; forming an insulating layer on the amorphous silicon layer pattern; forming a gate electrode on a part of the insulating layer which corresponds to the amorphous silicon layer pattern; forming a blocking film on the gate electrode and the insulating layer; doping an impurity in a part of the amorphous silicon layer pattern; annealing the amorphous silicon layer pattern on which the impurity is doped to form a semiconductor layer; removing the blocking film; etching the insulating layer using the gate electrode as a mask to form a gate insulating layer below the gate electrode; forming an interlayer insulating layer using an organic insulator on a buffer layer, the gate electrode, and the semiconductor layer.

### CROSS-REFERENCE TO RELATED APPLICATION

This application claims priority to and the benefit of Korean Patent Application No. 10-2013-0105394, filed in the Korean Intellectual Property Office on Sep. 3, 2013, the entire content of which is incorporated herein by reference.

### BACKGROUND

1. Field

The following description relates to an organic light emitting display and a method for manufacturing the same.

2. Description of the Related Art

An organic light emitting display includes a plurality of organic light emitting diodes which are formed of a hole injection electrode, an organic emission layer, and an electron injection electrode. Each organic light emitting diode emits light by the energy generated when the electron and the hole are coupled to each other in the organic emission layer to generate an exciton, and the exciton is changed from an excited state into a base state.

For such an organic light emitting display, a thin film transistor which includes a polycrystalline silicon having a high charge mobility is used.

Also, in a bendable flexible organic light emitting display of the related art, a stress of an inorganic insulating layer and a wiring line is weak so that cracks may occur in the thin film, and a device characteristic of the display device is degraded at a low curvature radius.

In order to solve the above-mentioned problems, the inorganic insulating layer is replaced with an organic film to improve the flexibility of the display device. However, in the case of an organic insulator, it is difficult to perform a high temperature process so that there is limitation on usage of a thin film transistor including a polycrystalline silicon.

The above information disclosed in this Background section is only for enhancement of understanding of the background of the invention and therefore it may contain information that does not form the prior art that is already known in this country to a person of ordinary skill in the art.

### SUMMARY

Aspects of embodiments of the present invention are directed toward a flexible organic light emitting display including a polycrystalline silicon in which an interlayer insulating layer is formed of an organic insulator utilizing a blocking film during a manufacturing process.

According to an example embodiment of the present invention, a method of manufacturing an organic light emitting display includes: sequentially forming a buffer layer and an amorphous silicon layer on a flexible substrate; patterning the amorphous silicon layer to form an amorphous silicon layer pattern; forming an insulating layer on the amorphous silicon layer pattern and the buffer layer; forming a gate electrode on a part of the insulating layer corresponding to the amorphous silicon layer pattern; forming a blocking film on the gate electrode and the insulating layer; doping an impurity in a part of the amorphous silicon layer pattern; annealing the amorphous silicon layer pattern on which the impurity is doped to form a semiconductor layer; removing the blocking film; etching the insulating layer using the gate electrode as a mask to form a gate insulating layer below the gate electrode; forming an interlayer insulating layer using an organic insulator on the buffer layer, the gate electrode, and the semiconductor layer; forming a source electrode and a drain electrode on the interlayer insulating layer; forming a passivation layer on the source electrode and the drain electrode; forming a pixel electrode on the passivation layer; forming an organic insulating layer on the pixel electrode; and forming a common electrode on the organic insulating layer.

The blocking film may include silicon nitride, silicon oxide or aluminum oxide.

The semiconductor layer may include polycrystalline silicon.

The semiconductor layer may include a channel region in which no impurity is doped, and a source region and a drain region in which an impurity is doped.

The annealing may be performed at a temperature of 400° C. or higher.

The passivation layer may include an organic insulator.

The gate insulating layer may have a single layer or a plurality of layers, the gate insulating layer may include at least one selected from the group consisting of silicon nitride and silicon oxide.

The gate insulating layer may be on the channel region of the semiconductor layer.

According to another example embodiment of the present invention, an organic light emitting display includes: a flexible substrate; a buffer layer on the flexible substrate; a semiconductor layer on the buffer layer and including polycrystalline silicon; a gate insulating layer on the semiconductor layer; a gate electrode on the gate insulating layer; an interlayer insulating layer including an organic insulator on the buffer layer and the gate electrode; a source electrode and a drain electrode on the interlayer insulating layer; a passivation layer on the source electrode and the drain electrode; and an organic light emitting diode on the passivation layer.

The organic light emitting diode may include a pixel electrode on the passivation layer, an organic emission layer on the pixel electrode, and a common electrode on the organic emission layer.

According to one or more embodiments of the present invention, when the amorphous silicon is annealed to be crystallized into a polycrystalline silicon, the blocking film is used so that there is no need to form the interlayer insulating layer by a high temperature process of 400° C. or higher, and thus the interlayer insulating layer may be formed of an organic insulator.

Accordingly, the flexibility of an organic light emitting display which includes a flexible substrate including polycrystalline silicon may be improved.

### BRIEF DESCRIPTION OF THE DRAWINGS

FIG. 1 is an equivalent circuit diagram of one pixel of an organic light emitting display according to an example embodiment of the present invention.

FIG. 2 is a layout view of one pixel of an organic light emitting display according to an example embodiment of the present invention.

FIG. 3 is a cross-sectional view taken along the line III-III of FIG. 2.

FIGS. 4 to 10 are views sequentially illustrating a manufacturing method of an organic light emitting display according to an example embodiment of the present invention.

### DETAILED DESCRIPTION

In the following detailed description, only certain example embodiments of the present invention have been shown and described, simply by way of illustration. As those skilled in the art would realize, the described embodiments may be modified in various different ways, all without departing from the spirit or scope of the present invention.

Accordingly, the drawings and description are to be regarded as illustrative in nature and not restrictive. Like reference numerals designate like elements throughout the specification.

In addition, the size and thickness of each configuration shown in the drawings are arbitrarily shown for understanding and ease of description, but the present invention is not limited thereto.

In the drawings, the thickness of layers, films, panels, regions, etc., are exaggerated for clarity. In the drawings, the thickness of layers, films, panels, regions, etc., are exaggerated for the convenience of description. It will be understood that when an element such as a layer, film, region, or substrate is referred to as being “on” another element, it can be directly on the other element or intervening elements may also be present.

In addition, unless explicitly described to the contrary, the word “comprise” and variations such as “comprises” or “comprising”, will be understood to imply the inclusion of stated elements but not the exclusion of any other elements. Further, in the specification, the word “on” refers to positioning above or below the object portion, but does not necessarily refers to positioning on the upper side of the object portion based on a gravity direction. Expressions such as “at least one of,” when preceding a list of elements, modify the entire list of elements and do not modify the individual elements of the list. Further, the use of “may” when describing embodiments of the present invention refers to “one or more embodiments of the present invention.”

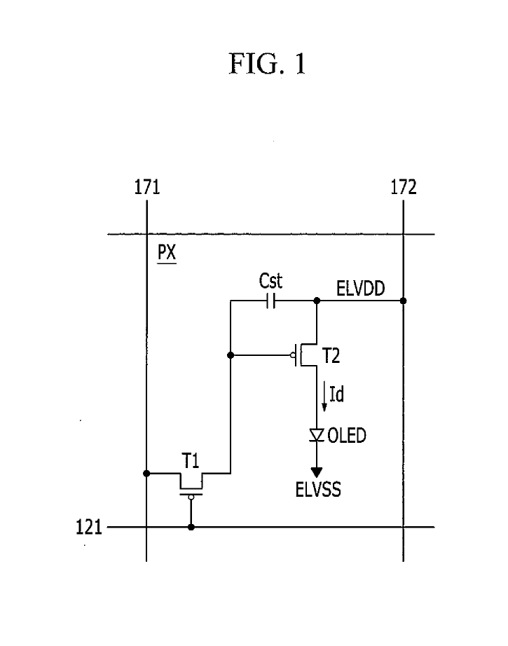

An organic light emitting display according to an example embodiment of the present invention will be described with reference to FIGS. 1 to 3.

FIG. 1 is an equivalent circuit diagram of one pixel of an organic light emitting display according to an example embodiment of the present invention.

Referring to FIG. 1, the organic light emitting display according to the present example embodiment includes a plurality of signal lines 121, 171, and 172 and a plurality of pixels PX which are connected to the signal lines and arranged substantially in a matrix.

The plurality of signal lines include a plurality of gate lines 121 which transmit a gate signal (or a scan signal), a plurality of data lines 171 which transmit a data signal, and a plurality of driving voltage lines 172 which transmit a driving voltage (ELVDD).

The gate lines 121 extend in a substantially row direction and are parallel to each other. The data lines 171 and the driving voltage lines 172 extend in a substantially column direction and are substantially parallel to each other, respectively.

Each pixel PX includes a switching thin film transistor T1, a driving thin film transistor T2, a storage capacitor Cst, and an organic light emitting diode (OLED).

The switching thin film transistor T1 includes a control terminal, an input terminal, and an output terminal. The control terminal is connected to the gate line 121, the input terminal is connected to the data line 171, and the output terminal is connected to the driving thin film transistor T2. The switching thin film transistor T1 transmits a data signal which is applied to the data line 171 to the driving thin film transistor T2 in response to a gate signal which is applied to the gate line 121.

The driving thin film transistor T2 also includes a control terminal, an input terminal, and an output terminal. The control terminal is connected to the switching thin film transistor T1, the input terminal is connected to the driving voltage line 172, and the output terminal is connected to the organic light emitting diode (OLED). The driving thin film transistor T2 flows an output current Id, the magnitude (e.g. the amplitude) of which varies depending on a voltage which is applied between the control terminal and the output terminal.

The storage capacitor Cst is connected between the control terminal and the input terminal of the driving thin film transistor T2. The storage capacitor Cst charges the data signal which is applied to the control terminal of the driving thin film transistor T2 and holds the data signal after the switching thin film transistor T1 is turned off.

The organic light emitting diode (OLED) includes an anode which is connected to the output terminal of the driving thin film transistor T2 and a cathode which is connected to a common voltage (ELVSS). The organic light emitting diode (OLED) emits light by varying an intensity of the light in accordance with the output current Id of the driving thin film transistor T2 to display an image.

The switching thin film transistor T1 and the driving thin film transistor T2 may be an n channel electric field effect transistor (FET) or a p channel electric field effect transistor. Further, the connection relationship of the thin film transistors T1 and T2, the storage capacitor Cst, and the organic light emitting diode (OLED) may be changed.

Hereinafter, an example structure of a pixel of the organic light emitting display illustrated in FIG. 1 will be described in more detail with reference to FIGS. 1, 2, and 3.

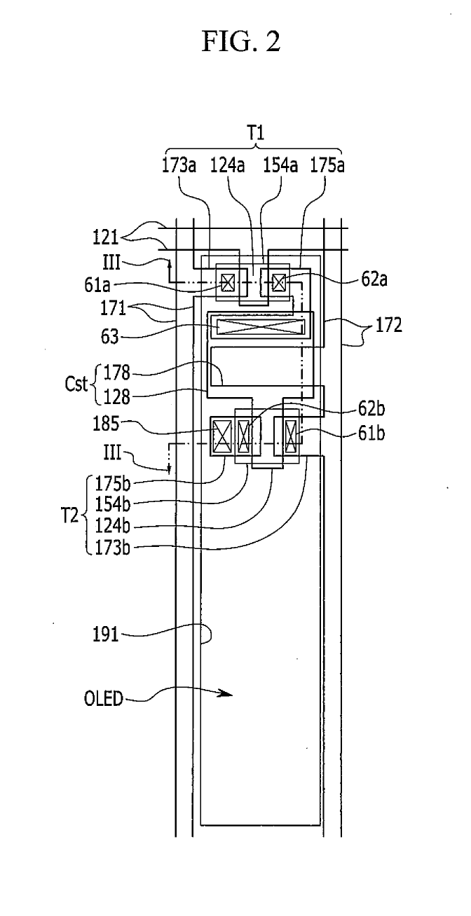

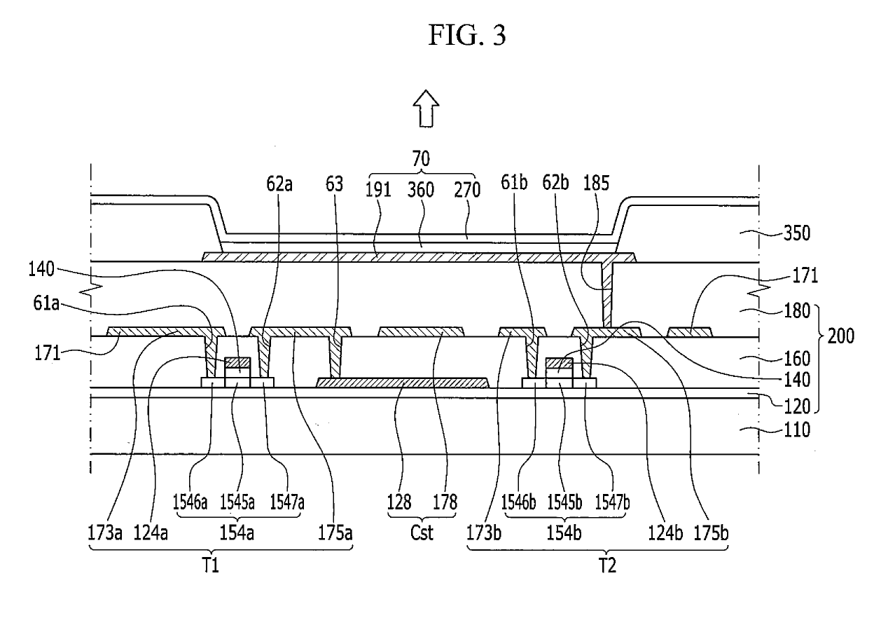

FIG. 2 is a layout view of one pixel of an organic light emitting display according to an example embodiment of the present invention and FIG. 3 is a cross-sectional view taken along the line III-III of FIG. 2.

Referring to FIGS. 2 and 3, an organic light emitting display according to the present example embodiment includes a substrate 110, and a thin film display layer 200 and an organic light emitting diode 70 which are disposed on the substrate 110.

The substrate 110 is an insulating flexible substrate which is formed of plastic.

The thin film display layer 200 includes a buffer layer 120, switching and driving semiconductor layers 154a and 154b, a gate insulating layer 140, a gate line 121, a first storage capacitor plate 128, an interlayer insulating layer 160, a data line 171, a driving voltage line 172, a switching drain electrode 175a, a driving drain electrode 175b, and a passivation layer 180.

The buffer layer 120 is disposed on the substrate 110 and may be formed as a single layer of silicon nitride (SiNx) or a dual layer structure in which silicon nitride (SiNx) and silicon oxide (SiO₂) are laminated. The buffer layer 120 functions to planarize a surface while preventing unnecessary components, such as impurity or moisture from being permeated.

The switching semiconductor layer 154a and the driving semiconductor layer 154b are disposed on the buffer layer 120 so as to be spaced apart from each other. The switching semiconductor layer 154a and the driving semiconductor layer 154b are formed of polycrystalline silicon and include channel regions 1545a and 1545b, source regions 1546a and 1546b, and drain regions 1547a and 1547b, respectively. The source regions 1546a and 1546b and the drain regions 1547a and 1547b are disposed at both sides of the channel regions 1545a and 1545b, respectively.

The channel regions 1545a and 1545b are each formed of polysilicon on which no impurity is doped, that is, formed of intrinsic semiconductors. The source regions 1546a and 1546b and the drain regions 1547a and 1547b are each formed of polysilicon on which a conductive impurity is doped, that is, formed of impurity semiconductors.

The gate insulating layer 140 is disposed on the channel regions 1545a and 1545b of the switching semiconductor layer 154a and the driving semiconductor layer 154b. The gate insulating layer 140 may be a single layer or plural layers, and include at least one of silicon nitride and silicon oxide.

The gate line 121 is disposed on the gate insulating layer 140, and the first storage capacitor plate 128 is disposed on the buffer layer 120.

The gate line 121 extends in a horizontal direction to transmit a gate signal and includes a switching gate electrode 124a which protrudes from the gate line 121 to the switching semiconductor layer 154a. The first storage capacitor plate 128 includes a driving gate electrode 124b, which protrudes from the first storage capacitor plate 128 to the driving semiconductor layer 154b. The switching gate electrode 124a and the driving gate electrode 124b overlap the channel regions 1545a and 1545b, respectively.

The interlayer insulating layer 160 is disposed on the gate line 121, the first storage capacitor plate 128, and the buffer layer 120.

The interlayer insulating layer 160 is formed of an organic insulator and a surface thereof may be flat. A switching source contact hole 61a and a switching drain contact hole 62a are formed in the interlayer insulating layer 160 to expose the source region 1546a and the drain region 1547a of the switching semiconductor layer 154a, respectively. Further, a driving source contact hole 61b and a driving drain contact hole 62b are formed in the interlayer insulating layer 160 to expose the source region 1546b and the drain region 1547b of the driving semiconductor layer 154b, respectively.

A data line 171, a driving voltage line 172, a switching drain electrode 175a, and a driving drain electrode 175b are disposed on the interlayer insulating layer 160.

The data line 171 includes a switching source electrode 173a, which transmits a data signal, extends in a direction crossing (or intersecting) the gate line 121, and protrudes from the data line 171 to the switching semiconductor layer 154a.

The driving voltage line 172 transmits a driving voltage, is separated from the data line 171, and extends in the same direction as the data line 171. The driving voltage line 172 includes a driving source electrode 173b, which protrudes from the driving voltage line 172 to the driving semiconductor layer 154b, and a second storage capacitor plate 178, which protrudes from the driving voltage line 172 to overlap the first storage capacitor plate 128. Here, the first storage capacitor plate 128 and the second storage capacitor plate 178 form a storage capacitor Cst utilizing the interlayer insulating layer 160 as a dielectric material.

The switching drain electrode 175a faces the switching source electrode 173a, and the driving drain electrode 175b faces the driving source electrode 173b.

The switching source electrode 173a and the switching drain electrode 175a are connected with the source region 1546a and the drain region 1547a of the switching semiconductor layer 154a through the switching source contact hole 61a and the switching drain contact hole 62a, respectively. Further, the switching drain electrode 175a extends to be electrically connected with the first storage capacitor plate 128 and the driving gate electrode 124b through a first contact hole 63 which is formed in the interlayer insulating layer 160.

The driving source electrode 173b and the driving drain electrode 175b are connected with the source region 1546b and the drain region 1547b of the driving semiconductor layer 154b through the driving source contact hole 61b and the driving drain contact hole 62b, respectively.

The switching semiconductor layer 154a, the switching gate electrode 124a, the switching source electrode 173a, and the switching drain electrode 175a form the switching thin film transistor T1. The driving semiconductor layer 154b, the driving gate electrode 124b, the driving source electrode 173b, and the driving drain electrode 175b form the driving thin film transistor T2.

The passivation layer 180 is formed on the data line 171, the driving voltage line 172, the switching drain electrode 175a, and the driving drain electrode 175b.

The passivation layer 180 is formed of an organic insulator, and a surface thereof is flat. A second contact hole 185 is formed in the passivation layer 180 to expose the driving drain electrode 175b.

An organic light emitting diode 70 and a pixel definition layer 350 are disposed on the passivation layer 180.

The organic light emitting diode 70 includes a pixel electrode 191, an organic emission layer 360, and a common electrode 270.

The pixel electrode 191 is disposed on the passivation layer 180 and is electrically connected to the driving drain electrode 175b of the driving thin film transistor T2 through the second contact hole 185, which is formed in the interlayer insulating layer 160. Such a pixel electrode 191 becomes an anode electrode of the organic light emitting diode 70.

The pixel electrode 191 may be formed of a transparent conductive material such as indium tin oxide (ITO), indium zinc oxide (IZO), zinc oxide (ZnO) or indium oxide (In₂O₃) or a reflective metal such as lithium (Li), calcium (Ca), fluoride lithium/calcium (LiF/Ca), fluoride lithium/aluminum (LiF/Al), aluminum (Al), silver (Ag), magnesium (Mg), or gold (Au).

The pixel definition layer 350 is disposed on the passivation layer 180 and an edge of the pixel electrode 191.

The pixel definition layer 350 has an opening which exposes the pixel electrode 191. The pixel definition layer 350 may be formed of a polyacryl-based (polyacrylates) or polyimide-based (polyimides) resin.

The organic emission layer 360 is disposed on the pixel electrode 191, which is disposed in the opening of the pixel definition layer 350. The organic emission layer 360 is formed of a plurality of layers, and includes at least one of an emission layer, a hole injection layer (HIL), a hole transporting layer (HTL), an electron transporting layer (ETL), and an electron injection layer (EIL). When the organic emission layer 360 includes all of the above layers, the hole injection layer is disposed on the pixel electrode 191 which serves as an anode electrode, and the hole transporting layer, the emission layer, the electrode transporting layer, and the electron injection layer may be sequentially laminated thereon.

The organic emission layer 360 may include a red organic light emission layer which emits red light, a green organic emission layer which emits green light, and a blue organic emission layer which emits blue light, and the red organic emission layer, the green organic emission layer, and the blue organic emission layer may be formed in a red pixel, a green pixel, and a blue pixel respectively to implement a color image.

Further, in the organic emission layer 360, the red organic emission layer, the green organic emission layer, and the blue organic emission layer may be laminated in the red pixel, the green pixel, and the blue pixel all together, and a red color filter, a green color filter, and a blue color filter for every pixel may be formed to implement a color image. In another example, a white organic emission layer which emits white light may be formed in all of the red pixel, the green pixel, and the blue pixel, and a red color filter, a green color filter, and a blue color filter may be formed for every pixel to implement a color image. When the color image is implemented by using the white organic emission layer and the color filter, a deposition mask which deposits the red organic emission layer, the green organic emission layer, and the blue organic emission layer in each individual pixel, that is, the red pixel, the green pixel, and the blue pixel, may not need to be used.

The white organic emission layer which is described in another example may be not only formed as a single organic emission layer, but also include a structure in which a plurality of organic emission layers is laminated to emit white light. For example, the white organic emission layer may include a structure in which at least one yellow organic emission layer and at least one blue organic emission layer are combined to emit white light, a structure in which at least one cyan organic emission layer and at least one red organic emission layer are combined to emit white light, or a structure in which at least one magenta organic emission layer and at least one green organic emission layer are combined to emit white light.

The common electrode 270 is disposed on the pixel definition layer 350 and the organic emission layer 360. The common electrode 270 may be formed of a transparent conductive material such as ITO, IZO, ZnO or In₂O₃; or a reflective metal such as lithium, calcium, fluoride lithium/calcium, fluoride lithium/aluminum, aluminum, silver, magnesium, or gold. Such a common electrode 270 becomes a cathode electrode of the organic light emitting diode 70.

As described above, the interlayer insulating layer 160 is formed of an organic insulator so that the flexibility of an organic light emitting display which includes a flexible substrate and polycrystalline silicon may be improved.

Now, a manufacturing method of an organic light emitting display according to an example embodiment of the present invention will be described in more detail with reference to FIGS. 3, and 4 to 10.

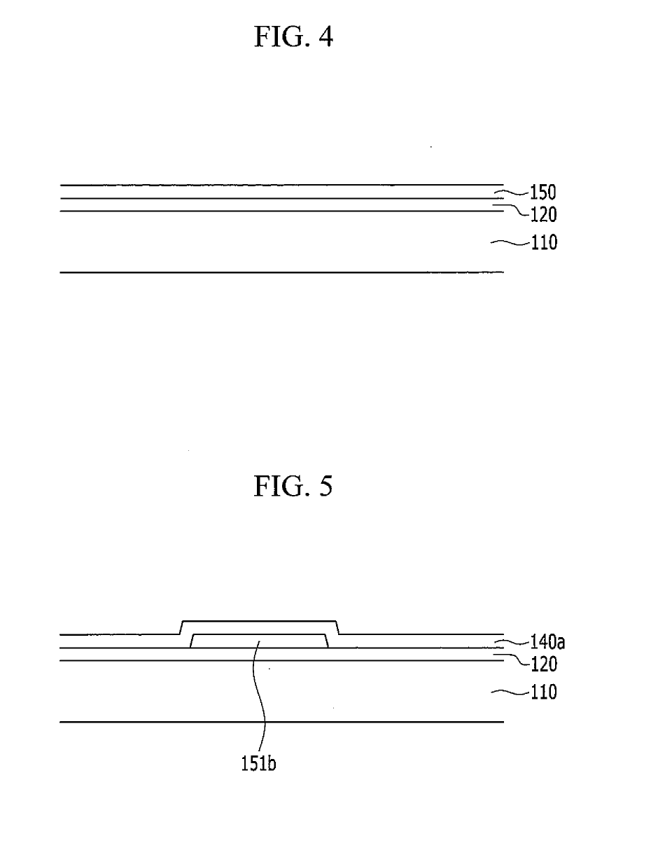

FIGS. 4 to 10 are views sequentially illustrating a manufacturing method of an organic light emitting display according to an example embodiment of the present invention.

In FIGS. 4 to 10, a manufacturing method of a switching thin film transistor T1 is not illustrated but a manufacturing method of a driving thin film transistor T2 is illustrated because the manufacturing method of the driving thin film transistor T2 is substantially the same as the manufacturing method of the switching thin film transistor T1.

Referring to FIG. 4, a buffer layer 120 and an amorphous silicon layer 150 are sequentially formed on an insulating flexible substrate 110 which is formed of plastic. The buffer layer 120 is formed as a single layer of silicon nitride or a dual layer structure in which silicon nitride and silicon oxide are stacked or laminated.

Referring to FIG. 5, after patterning the amorphous silicon layer 150 to form a driving amorphous silicon layer pattern 151b, an insulating layer 140a is formed on the buffer layer 120 and the driving amorphous silicon layer pattern 151b. The insulating layer 140a is formed of a single layer or a plurality of layers, and includes at least one of silicon nitride and silicon oxide.

Also, when the driving amorphous silicon layer pattern 151b is formed, a switching amorphous silicon layer pattern is also formed.

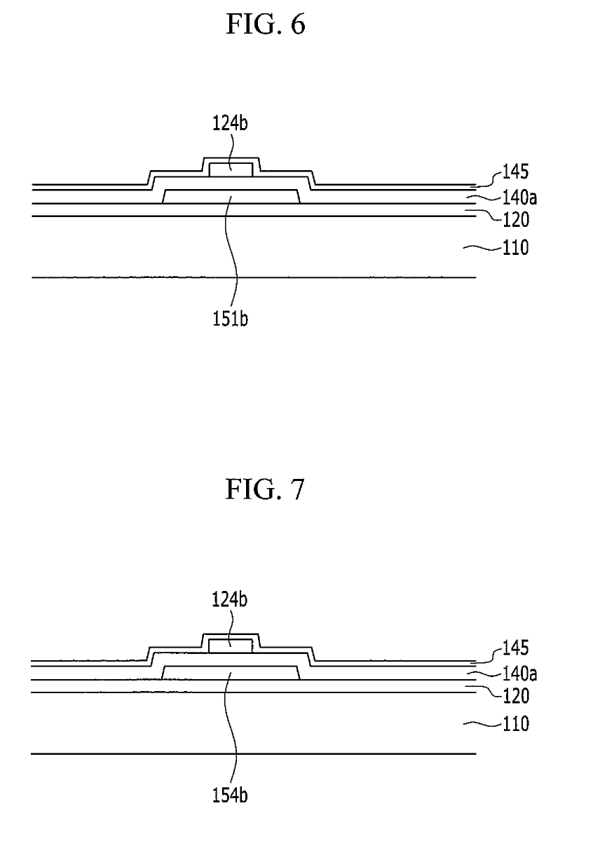

Referring to FIG. 6, after forming the driving gate electrode 124b on the insulating layer 140a, a blocking film 145 is formed on the driving gate electrode 124b and the insulating layer 140a. The driving gate electrode 124b overlaps the driving amorphous silicon layer pattern 151b.

Also, when the driving gate electrode 124b is formed, a gate line 121 (which includes a switching gate electrode 124a) and a first storage capacitor plate 128 are also formed.

The blocking film 145 may be formed of silicon nitride, silicon oxide, or aluminum oxide (AlOx). The blocking film 145 may be formed of silicon nitride or silicon oxide in a vacuum environment, or the blocking film 145 may be formed of aluminum oxide (AlOx) in a non-vacuum environment.

Thereafter, an impurity is doped in a portion of the driving amorphous silicon layer pattern 151b, which does not overlap the driving gate electrode 124b. Here, the impurity may vary depending on a type of a thin film transistor so that an n-type (e.g., n-channel) impurity or a p-type (e.g., p-channel) impurity may be doped.

Referring to FIG. 7, annealing is performed at a temperature of 400° C. or higher to crystallize the driving amorphous silicon layer pattern 151b to form the driving semiconductor layer 154b, which includes polycrystalline silicon.

Here, the doped impurity is activated to form a source region 1546b and a drain region 1547b of the driving semiconductor layer 154b. A region on which no impurity is doped becomes a channel region 1545b of the driving semiconductor layer 154b.

Also, when the driving semiconductor layer 154b is formed, a switching semiconductor layer 154a is also formed.

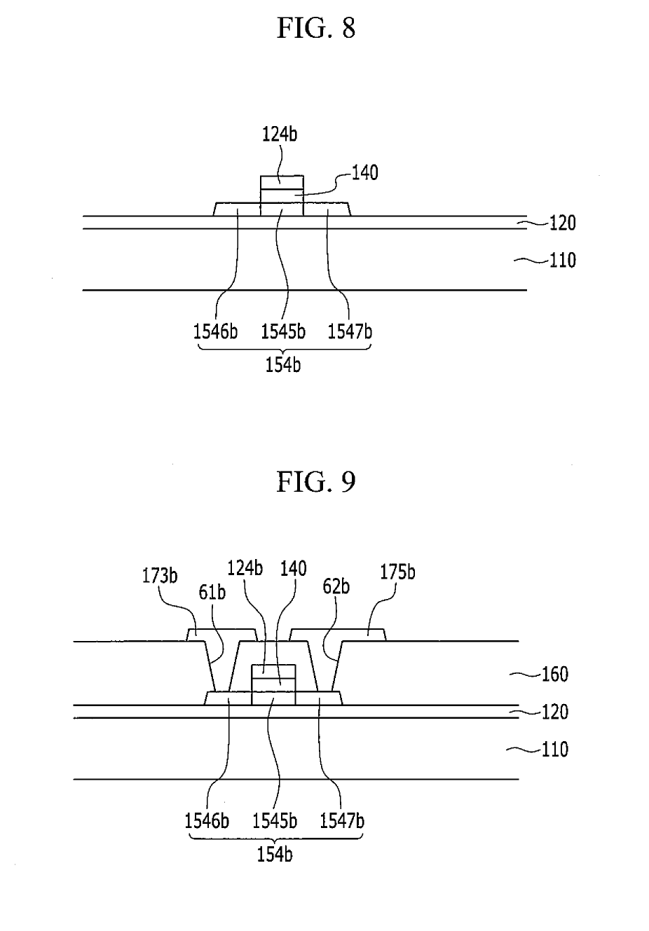

The blocking film 145 is then removed. Referring to FIG. 8, after removing the blocking film 145, the insulating layer 140a is etched using the driving gate electrode 124b as a mask to form a gate insulating layer 140 below the driving gate electrode 124b. The etching may be wet etching or dry etching.

Here, the gate insulating layer 140 is also formed below the switching gate electrode 124a.

Referring to FIG. 9, an interlayer insulating layer 160 is formed on the buffer layer 120, the driving gate electrode 124b, and the source region 1546b and the drain region 1547b of the driving semiconductor layer 154b utilizing an organic insulator, and then a driving source contact hole 61b and a driving drain contact hole 62b, which expose the source region 1546b and the drain region 1547b of the driving semiconductor layer 154b respectively are formed in the interlayer insulating layer 160.

Here, a switching source contact hole 61a and a switching drain contact hole 62a which expose the source region 1546a and the drain region 1547a of the switching semiconductor layer 154a respectively are also formed.

Thereafter, the driving source electrode 173b and the driving drain electrode 175b are formed. The driving source electrode 173b and the driving drain electrode 175b are connected to the source region 1546b and the drain region 1547b of the driving semiconductor layer 154b through the driving source contact hole 61b and the driving drain contact hole 62b, respectively.

Here, a switching source electrode 173a and a switching drain electrode 175a are also formed. The switching source electrode 173a and the switching drain electrode 175a are connected to the source region 1546a and the drain region 1547a of the switching semiconductor layer 154a through the switching source contact hole 61a and the switching drain contact hole 62a, respectively.

Further, a data line 171 and a driving voltage line 172 (which includes a second storage capacitor plate 178) are also formed.

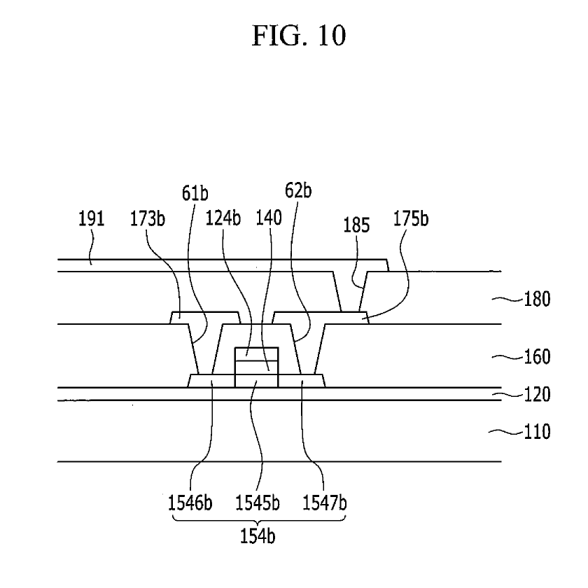

Referring to FIG. 10, a passivation layer 180 is formed on the interlayer insulating layer 160, the driving source electrode 173b, and the driving drain electrode 175b utilizing an organic insulator, and then a pixel electrode 191, which is connected to the driving drain electrode 175b through a second contact hole 185, is formed on the passivation layer 180.

Referring to FIG. 3, a pixel definition layer 350 is formed on an edge of the pixel electrode 191 and the passivation layer 180, the organic emission layer 360 is formed on the pixel electrode 191 (which is disposed in the opening of the pixel definition layer 350), and then a common electrode 270 is formed on the pixel definition layer 350 and the organic emission layer 360.

As described above, when the amorphous silicon is annealed to be crystallized as polycrystalline silicon, the blocking film 145 is used so that there is no need to form the interlayer insulating layer 160 by a high temperature process of 400° C. or higher, and thus the interlayer insulating layer 160 may be formed of an organic insulator. Accordingly, the flexibility of an organic light emitting display which includes a flexible substrate and polycrystalline silicon may be improved.

While this invention has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims, and equivalents thereof.

Description of certain symbols

| | |
|---|---|
| 70: Organic light emitting diode | 110: Substrate |
| 120: Buffer layer | 121: Gate line |
| 140: Gate insulating layer | 145: Blocking film |
| 150: Amorphous silicon layer | 154a, 154b: Semiconductor layer |
| 160: Interlayer insulating layer | 171: Data line |
| 172: Driving voltage line | 180: Passivation layer |
| 191: Pixel electrode | 270: Common electrode |
| 360: Organic emission layer | |

What is claimed is:

1. A method of manufacturing an organic light emitting display, the method comprising:
sequentially forming a buffer layer and an amorphous silicon layer on a flexible substrate;
patterning the amorphous silicon layer to form an amorphous silicon layer pattern;
forming an insulating layer on the amorphous silicon layer pattern and the buffer layer;
forming a gate electrode on a part of the insulating layer corresponding to the amorphous silicon layer pattern;
forming a blocking film on the gate electrode and the insulating layer;
doping an impurity in a part of the amorphous silicon layer pattern;
annealing the amorphous silicon layer pattern on which the impurity is doped to form a semiconductor layer;
removing the blocking film;
etching the insulating layer utilizing the gate electrode as a mask to form a gate insulating layer below the gate electrode;
forming an interlayer insulating layer utilizing an organic insulator on the buffer layer, the gate electrode, and the semiconductor layer;
forming a source electrode and a drain electrode on the interlayer insulating layer;
forming a passivation layer on the source electrode and the drain electrode;
forming a pixel electrode on the passivation layer;
forming an organic insulating layer on the pixel electrode; and
forming a common electrode on the organic insulating layer.

2. The method of claim 1, wherein the blocking film comprises silicon nitride, silicon oxide, or aluminum oxide.

3. The method of claim 2, wherein the semiconductor layer comprises polycrystalline silicon.

4. The method of claim 3, wherein the semiconductor layer comprises a channel region in which no impurity is doped, and a source region and a drain region in each of which an impurity is doped.

5. The method of claim 4, wherein the annealing is performed at a temperature of 400° C. or higher.

6. The method of claim 5, wherein the passivation layer comprises the organic insulator.

7. The method of claim 6, wherein the gate insulating layer is a single layer or a plurality of layers, and the gate insulating layer comprises at least one selected from the group consisting of silicon nitride and silicon oxide.

8. The method of claim 7, wherein the gate insulating layer is on the channel region of the semiconductor layer.

9. An organic light emitting display, comprising:
a flexible substrate;
a buffer layer on the flexible substrate;
a semiconductor layer on the buffer layer and comprising polycrystalline silicon;
a gate insulating layer on the semiconductor layer;
a gate electrode on the gate insulating layer;
an interlayer insulating layer comprising an organic insulator on the buffer layer and the gate electrode;
a source electrode and a drain electrode on the interlayer insulating layer;
a passivation layer on the source electrode and the drain electrode; and
an organic light emitting diode on the passivation layer.

10. The organic light emitting display of claim 9, wherein the semiconductor layer comprises a channel region in which no impurity is doped, and a source region and a drain region in each of which an impurity is doped.

11. The organic light emitting display of claim 10, wherein the gate insulating layer is on a channel region of the semiconductor layer.

12. The organic light emitting display of claim 11, wherein the passivation layer comprises an organic insulator.

13. The organic light emitting display of claim 12, wherein the gate insulating layer is a single layer or a plurality of layers, and the gate insulating layer comprises at least one selected from the group consisting of silicon nitride and silicon oxide.

14. The organic light emitting display of claim 13, wherein the organic light emitting diode comprises:
a pixel electrode on the passivation layer;
an organic emission layer on the pixel electrode; and
a common electrode on the organic emission layer.
